(19) United States
(12) Patent Application Publication
(10) Pub. No.: US 2024/0274466 A1
(43) Pub. Date: Aug. 15, 2024

(54) SEMICONDUCTOR STRUCTURE AND FORMING METHOD THEREOF

(71) Applicant: Semiconductor Manufacturing International (Shanghai) Corporation, Shanghai (CN)

(72) Inventors: Yichao WU, Shanghai (CN); Jisong JIN, Shanghai (CN)

(73) Assignee: Semiconductor Manufacturing International (Shanghai) Corporation, Shanghai (CN)

(21) Appl. No.: 18/203,829

(22) Filed: May 31, 2023

(30) Foreign Application Priority Data
Feb. 10, 2023 (CN) 202310099772.4

(51) Int. Cl. H01L 21/768; H01L 23/522; H01L 23/528; H01L 23/532

(52) U.S. Cl. CPC H01L 21/7682; H01L 21/76802; H01L 23/5222; H01L 23/528; H01L 23/53238

(57) ABSTRACT

In one form, a method includes: providing a base, where a bottom film layer structure is formed on the base and includes a plurality of discrete first regions and a plurality of second regions located among the first regions; forming top conductive layers on the bottom film layer structure of the first regions, where openings are enclosed between the adjacent top conductive layers and the bottom film layer structure; forming grooves in the bottom film layer structure at bottoms of the openings, where bottoms of the grooves are lower than bottoms of the top conductive layers; and forming a first dielectric layer on the top conductive layers, where the first dielectric layer is further located in the grooves, seals tops of the openings and encloses air gaps together with the openings, and bottoms of the air gaps are lower than the bottoms of the top conductive layers.

### RELATED APPLICATIONS

The present application claims priority to Chinese Patent Application No. 202310099772.4, filed on Feb. 10, 2023, the entire content of which is incorporated herein by reference.

### TECHNICAL FIELD

Embodiments and implementations of the present disclosure relate to the field of semiconductor fabrication, in particular to a semiconductor structure and a forming method thereof.

### BACKGROUND

In semiconductor fabrication, in the development tendency of a super-large-scale integrated circuit, a feature size of the integrated circuit decreases continuously, the area of a chip increases continuously, and a back-end-of-line interconnect resistance capacitor (RC) delay tends to increase significantly, which affects the performance of a semiconductor device.

Parasitic capacitance and interconnect resistance between back-end-of-line interconnect structures are two main factors of the RC delay. As the parasitic capacitance C is in direct proportion to a relative dielectric constant k of an interlayer dielectric layer, a low-k porous material has been widely used as the interlayer dielectric layer of an interconnect structure now. Besides, copper has lower resistivity, an excellent anti-electromigration characteristic and high reliability, interconnect resistance of metal can be reduced, and thus the back-end-of-line interconnect RC delay is reduced, so conventional aluminum interconnect has changed to copper interconnect with low resistance in the prior art. However, a performance of a semiconductor structure still needs to be improved.

### SUMMARY

A problem addressed by embodiments and implementations of the present disclosure is to provide a semiconductor structure and a forming method thereof, which improves consistency and stability of a capacitance value between adjacent top conductive layers and improves RC delay performance of the semiconductor structure.

To address the above problem, embodiments and implementations of the present disclosure provides a semiconductor structure. In one form, a semiconductor structure includes: a base; a bottom film layer structure, located on the base and including a plurality of discrete first regions and a plurality of second regions located among the first regions; top conductive layers, located on the bottom film layer structure of the first regions, where openings are enclosed between the adjacent top conductive layers and the bottom film layer structure; grooves, located in the bottom film layer structure at bottoms of the openings, where bottoms of the grooves are lower than bottoms of the top conductive layers; a first dielectric layer, located on the top conductive layers and further located in the grooves, where the first dielectric layer seals tops of the openings and encloses air gaps together with the openings, and bottoms of the air gaps are lower than the bottoms of the top conductive layers.

The present disclosure further provides a forming method of a semiconductor structure. In one form, a method includes: providing a base, where a bottom film layer structure is formed on the base and includes a plurality of discrete first regions and second regions located among the first regions; forming top conductive layers on the bottom film layer structure of the first regions, where openings are enclosed between the adjacent top conductive layers and the bottom film layer structure; forming grooves in the bottom film layer structure at bottoms of the openings, where bottoms of the grooves are lower than bottoms of the top conductive layers; and forming a first dielectric layer on the top conductive layers, where the first dielectric layer is further located in the grooves, seals tops of the openings and encloses air gaps together with the openings, and bottoms of the air gaps are lower than the bottoms of the top conductive layers.

Compared with the prior art, technical solutions of embodiments and implementations of the present disclosure have at least the following advantages: according to forms of a semiconductor structure provided by the present disclosure, the grooves are further formed and located in the bottom film layer structure at the bottoms of the openings, and the bottoms of the grooves are lower than the bottoms of the top conductive layers; the first dielectric layer is located on the top conductive layers and further located in the grooves, and the first dielectric layer seals the tops of the openings and encloses the air gaps together with the openings; a forming space can be provided for the first dielectric layer at the bottoms of the openings by means of arrangement of the grooves, so that the bottoms of the air gaps enclosed in the first dielectric layer located in the grooves and the openings can be lower than the bottoms of the top conductive layers, thus improvement of proportion consistency of the air gaps in an insulated dielectric between the adjacent top conductive layers is facilitated, consistency of compositions of the insulated dielectric between relative areas between the adjacent top conductive layers is improved correspondingly, thus consistency and stability of the capacitance value between the adjacent top conductive layers are improved, the RC delay performance of the semiconductor structure is improved, and performance of the semiconductor structure is improved.

In forms of a forming method of the semiconductor structure provided by the present disclosure, after the top conductive layers are formed, the grooves are further formed in the bottom film layer structure exposed out of the top conductive layers, the bottoms of the grooves are lower than the bottoms of the top conductive layers, and thus in the step of forming the first dielectric layer on the top conductive layers, the first dielectric layer is further located in the grooves, and the first dielectric layer seals the tops of the openings and encloses the air gaps together with the openings; the forming space can be provided for the first dielectric layer at the bottoms of the openings by means of arrangement of the grooves, so that the bottoms of the air gaps enclosed in the first dielectric layer located in the grooves and the openings can be lower than the bottoms of the top conductive layers. Thus, improvement of proportion consistency of the air gaps in the insulated dielectric between the adjacent top conductive layers is facilitated, consistency of compositions of the insulated dielectric between relative areas between the adjacent top conductive layers is improved correspondingly, thus consistency and stability of the capacitance value between the adjacent top conductive layers are improved, the RC delay performance of the semiconductor structure is improved, and performance of the semiconductor structure is improved.

### BRIEF DESCRIPTION OF THE DRAWINGS

FIG. 1 to FIG. 3 are corresponding schematic structural diagrams of steps in a forming method of a semiconductor structure.

FIG. 4 is a schematic structural diagram of one form of a semiconductor structure of the present disclosure.

FIG. 5 to FIG. 9 are corresponding schematic structural diagrams of steps in one form of a forming method of a semiconductor structure of the present disclosure.

### DETAILED DESCRIPTION

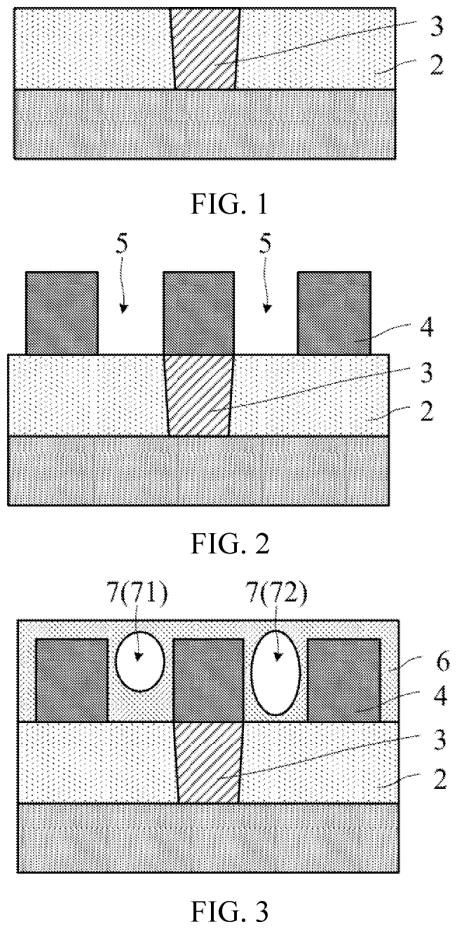

It may be seen from the background that performance of a conventional semiconductor structure needs to be improved. Why the performance of the semiconductor structure needs to be improved is analyzed below in combination with a forming method of the semiconductor structure. FIG. 1 to FIG. 3 are corresponding schematic structural diagrams of steps in a forming method of a semiconductor structure.

Referring to FIG. 1, a base (now shown in the figures) is provided, where a bottom dielectric layer 2 is formed on the base and includes a plurality of discrete first regions (not marked) and second regions (not marked) located among the first regions; and conductive plugs 3 are formed in at least a part of first regions and penetrate through the bottom dielectric layer 2.

Referring to FIG. 2, top interconnect wires 4 are formed on the bottom dielectric layer 2 and the conductive plugs 3 of the first regions, and openings 5 are enclosed between the adjacent top interconnect wires 4 and the bottom dielectric layer 2.

Referring to FIG. 3, a first dielectric layer 6 is formed on the top interconnect wires 4 and further formed in the openings 5, the first dielectric layer 6 seals tops of the openings 5 and encloses air gaps 7 together with the openings 5.

In the above forming method, the first dielectric layer 6 is further formed in the openings 5, and the first dielectric layer 6 located at top corners of the top interconnect wires 4 makes contact so as to seal the tops of the openings 5 and enclose the air gaps 7 together with the openings 5.

However, sizes and positions of the air gaps 7 formed in this way are instable, as shown in FIG. 3, a size and a position of the air gap 71 differ from a size and a position of the air gap 72, which results in that compositions of an insulated dielectric between the top interconnect wires 4 located on two sides of the air gap 71 differ from compositions of an insulated dielectric between the top interconnect wires 4 located on two sides of the air gap 72, that is, proportions of the air gaps 7 in the insulated dielectric between the adjacent top interconnect wires 4 are different, consequently, capacitance values between the adjacent top interconnect wires 4 in different positions in the semiconductor structure are different, consistency and stability of the capacitance values in the different positions are poor, and then the performance of the semiconductor structure will be reduced, especially, RC delay performance of the semiconductor structure will be reduced.

To address the technical problem, embodiments and implementations of the present disclosure provides a semiconductor structure. In one form, a semiconductor structure includes: a base; a bottom film layer structure, located on the base and including a plurality of discrete first regions and a plurality of second regions located among the first regions; top conductive layers, located on the bottom film layer structure of the first regions, where openings are enclosed between the adjacent top conductive layers and the bottom film layer structure; grooves, located in the bottom film layer structure at bottoms of the openings, where bottoms of the grooves are lower than bottoms of the top conductive layers; and a first dielectric layer, located on the top conductive layers and further located in the grooves, where the first dielectric layer seals tops of the openings and encloses air gaps together with the openings, and bottoms of the air gaps are lower than the bottoms of the top conductive layers.

In forms of a semiconductor structure provided by the present disclosure, the grooves are further formed and located in the bottom film layer structure at the bottoms of the openings, and the bottoms of the grooves are lower than the bottoms of the top conductive layers; the first dielectric layer is located on the top conductive layers and further located in the grooves, and the first dielectric layer seals the tops of the openings and encloses the air gaps together with the openings; a forming space can be provided for the first dielectric layer at the bottoms of the openings by means of arrangement of the grooves, so that the bottoms of the air gaps enclosed in the first dielectric layer located in the grooves and the openings can be lower than the bottoms of the top conductive layers, thus improvement of proportion consistency of the air gaps in an insulated dielectric between the adjacent top conductive layers is facilitated, consistency of compositions of the insulated dielectric between relative areas between the adjacent top conductive layers is improved correspondingly. Thus, consistency and stability of the capacitance value between the adjacent top conductive layers are improved, the RC delay performance of the semiconductor structure is improved, and performance of the semiconductor structure is improved.

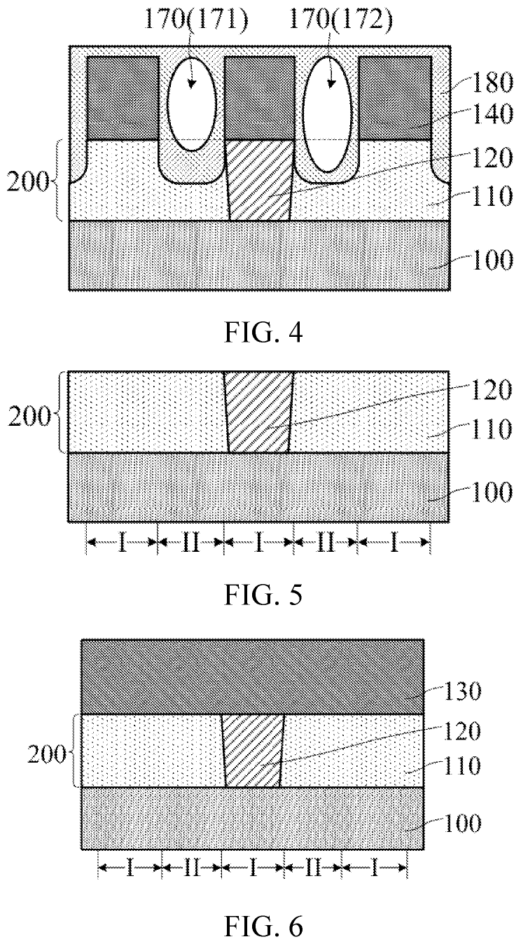

In order to make the above objectives, features and advantages of embodiments and implementations of the present disclosure clearer and easier to understand, specific embodiments and implementations of the present disclosure are described in detail below with reference to the accompanying drawings. FIG. 4 is a schematic structural diagram of one form of a semiconductor structure of the present disclosure.

As shown in FIG. 4, in one form, a semiconductor structure includes: the base (not shown in the figure); the bottom film layer structure 200, located on the base and including the plurality of discrete first regions I and the second regions II located among the first regions I; the top conductive layers 140, located on the bottom film layer structure 200 of the first regions I, where the openings 150 are enclosed between the adjacent top conductive layers 140 and the bottom film layer structure 200 (with reference to FIG. 7); the grooves 160 (with reference to FIG. 8), located in the bottom film layer structure 200 at the bottoms of the openings 150, where the bottoms of the grooves 160 are lower than the bottoms of the top conductive layers 140; and the first dielectric layer 180, located on the top conductive layers 140 and further located in the grooves 160, where the first dielectric layer 180 seals the tops of the openings 150 and encloses the air gaps 170 together with the openings 150, and the bottoms of the air gaps 170 are lower than the bottoms of the top conductive layers 140.

The base is configured to provide a process platform for forming of the semiconductor structure.

As an example, the base includes a substrate and a functional structure located on the substrate. For example, the functional structure may include a semiconductor device such as an MOS transistor, a resistor structure and the like. As an example, the MOS transistor includes a gate structure located on the substrate and a source/drain doped region in the substrate on two sides of the gate structure.

The bottom film layer structure 200 is configured to provide a platform for forming of the top conductive layers 140.

The bottom film layer structure 200 of the first regions I is configured to provide a process platform for forming the top conductive layers 140, and the bottom film layer structure 200 of the second regions II is configured to form the grooves 160.

As an example, the bottom film layer structure 200 includes conductive plugs 120 located in at least a part of the first regions I and a second dielectric layer 110 located between the conductive plugs 120.

The conductive plugs 120 are configured to be electrically connected with the top conductive layers 140 so that an electrical connection between the top conductive layers 140 and the functional structure in the base is implemented through the conductive plugs 120.

A material of the conductive plugs 120 is a conductive material. As an example, the material of the conductive plugs 120 is metal. In this implementation, the material of the conductive plugs 120 is Cu. In other implementations, the material of the conductive plugs may also be AL, W, Co and other conductive materials.

The second dielectric layer 110 is configured to implement an electrical isolation between the conductive plugs 120.

A material of the second dielectric layer 110 is an insulated dielectric material. As an example, the material of the second dielectric layer 110 may be a low-k dielectric material, an ultra-low-k dielectric material, silicon oxide, silicon nitride or silicon oxynitride and other dielectric materials.

It is to be noted that in this implementation, a third dielectric layer (not shown in the figures) is further formed between the base and the bottom film layer structure 200, and bottom interconnect wires 100 are formed in the third dielectric layer. Correspondingly, the conductive plugs 120 are located on the bottom interconnect wires 100 and make contact with the bottom interconnect wires 100.

The bottom interconnect wires 100 make contact with the conductive plugs 120, so that an electrical connection between the bottom interconnect wires 100 and the top conductive layers 140 is implemented through the conductive plugs 120.

In this implementation, the bottom interconnect wires 100 are electrically connected with the functional structure in the base, so that the electrical connection between the functional structure in the base and the top conductive layers 140 is implemented through the bottom interconnect wires 100 and the conductive plugs 120.

A material of the bottom interconnect wires 100 is a conductive material. As an example, the material of the bottom interconnect wires 100 is metal. In this implementation, the material of the bottom interconnect wires 100 is Cu. In other implementations, the material of the bottom interconnect wires may also be Al, W, Co and other conductive materials.

The third dielectric layer is configured to implement an electrical isolation between the bottom interconnect wires.

A material of the third dielectric layer is an insulated dielectric material. As an example, the material of the third dielectric layer may be a low-k dielectric material, an ultra-low-k dielectric material, silicon oxide, silicon nitride or silicon oxynitride and other dielectric materials.

The top conductive layers 140 are configured to implement an electrical connection between the semiconductor structure and an external circuit or other interconnect structures.

In this implementation, the top conductive layers 140 make contact with the conductive plugs 120 to be electrically connected with the conductive plugs 120 so as to implement the electrical connection with the functional structure in the base through the conductive plugs 120.

More specifically, in this implementation, the top conductive layers 140 are configured to serve as top interconnect wires to be electrically connected with the bottom interconnect wires 100 through the conductive plugs 120.

As an example, an extension direction of the top interconnect wires is perpendicular to an extension direction of the bottom interconnect wires 100. In other implementations, the extension direction of the top interconnect wires may also be the same as the extension direction of the bottom interconnect wires.

In this implementation, the openings 150 are enclosed between the adjacent top conductive layers 140 and configured to enclose the air gaps 170 together with the first dielectric layer 180.

A material of the top conductive layers 140 is a conductive material. As an example, the material of the top conductive layers 140 is metal. In this implementation, the material of the top conductive layers 140 is Cu. In other implementations, the material of the top conductive layers may also be Al, W, Co, Ni and other conductive materials.

The grooves 160 are located in the bottom film layer structure 200 at the bottoms of the openings 150, the bottoms of the grooves 160 are lower than the bottoms of the top conductive layers 140, so that the grooves 160 can provide the forming space for the first dielectric layer 180 at the bottoms of the openings 150, the first dielectric layer 180 located in the grooves 160 is prevented from occupying too much space of the openings 150 advantageously, and thus the bottoms of the air gaps 170 enclosed in the first dielectric layer 180 located in the grooves 160 and the openings 150 can be lower than the bottoms of the top conductive layers 140 advantageously.

In this implementation, the top conductive layers 140 are configured to serve as top interconnect wires, and the second dielectric layer 110 with part of thickness further remains at the bottoms of the grooves 160, so that the bottoms of the grooves 160 are prevented from exposing the bottom interconnect wires 100, and thus completeness of the bottom interconnect wires 100 and electrical connection performance of the semiconductor structure are guaranteed advantageously.

Correspondingly, in this implementation, the grooves 160 are located in the second dielectric layer 110 with part of thickness in the second regions II.

It is to be noted that depths of the grooves 160 are not suitable for being too small or too large. If the depths of the grooves 160 are too small, the space provided by the grooves 160 for the first dielectric layer 180 at the bottoms of the openings 150 is prone to being too small, and then the bottoms of the air gaps 170 enclosed in the first dielectric layer 180 located in the grooves 160 and the openings 150 are prone to being higher than the bottoms of the top conductive layers 140; and if the depths of the grooves 160 are too large, depth-to-width ratios of the grooves 160 are prone to being too large, process difficulty of forming the grooves 160 is prone to increasing correspondingly. Moreover, a risk of exposing the bottom interconnect wires 100 is also prone to increasing in a process of forming the grooves 160. Therefore, in this implementation, the depth of each groove 160 is 100 Ångström to 200 Ångström.

The first dielectric layer 180 is configured to implement an electrical isolation between the adjacent top conductive layers 140.

The first dielectric layer 180 is configured to seal the tops of the openings 150 and enclose the air gaps 170 together with the openings 150, the air gaps 170 have a dielectric constant lower than that of a common dielectric material (such as: the low-k dielectric material or the ultra-low-k dielectric material) in a semiconductor process, and thus parasitic capacitance between the adjacent top conductive layers 140 is reduced advantageously, an RC delay is reduced, and then the performance of the semiconductor structure is improved.

Besides, in this implementation, the first dielectric layer 180 is further located in the grooves 160, the forming space can be provided for the first dielectric layer 180 at the bottoms of the openings 150 by means of arrangement of the grooves 160, and the first dielectric layer 180 is prevented from occupying too much space of the openings 150, so that the bottoms of the air gaps 170 enclosed in the first dielectric layer 180 located in the grooves 160 and the openings 150 can be lower than the bottoms of the top conductive layers 140, thus improvement of proportion consistency of the air gaps 170 in the insulated dielectric between the adjacent top conductive layers 140 is facilitated, consistency of the compositions of the insulated dielectric between the relative areas between the adjacent top conductive layers 140 is improved correspondingly, thus consistency and stability of the capacitance value between the adjacent top conductive layers 140 are improved, the RC delay performance of the semiconductor structure is improved, and the performance of the semiconductor structure is improved.

As an example, the first dielectric layer 180 is further located in the grooves 160, the first dielectric layer 180 located at the top corners of the top conductive layers 140 makes contact so as to seal the tops of the openings 150, and the first dielectric layer 180 located in the grooves 160 and the openings 150 encloses the air gaps 170.

As an example, as shown in FIG. 4, in specific implementation, sizes and positions of the air gaps 170 in different positions are different, for example: a bottom of the air gap 172 is lower than a bottom of the air gap 171, the bottoms of the air gaps 170 in the various positions are all lower than the bottoms of the top conductive layers 140 due to arrangement of the grooves 160, it is guaranteed that height proportion consistency of heights of the air gaps 170 in the various positions between the adjacent conductive layers 140 is good, thus improvement of proportion consistency of the air gaps 170 in the insulated dielectric between the adjacent top conductive layers 140 is facilitated, consistency of the compositions of the insulated dielectric between the relative areas between the adjacent top conductive layers 140 is improved correspondingly, and thus consistency and stability of the capacitance value between the adjacent top conductive layers 140 are improved.

A material of the first dielectric layer 180 is an insulated dielectric material. As an example, the material of the first dielectric layer 180 may be a low-k dielectric material, an ultra-low-k dielectric material, silicon oxide, silicon nitride or silicon oxynitride and other dielectric materials.

It is to be noted that in this implementation, a description is made by taking the top conductive layers 140 being top interconnect wires as an example, and the bottom film layer structure with part of thickness also remains at the bottoms of the grooves 160 correspondingly. Correspondingly, through the semiconductor structure of this embodiment, the proportion consistency of the air gaps 170 in the insulated dielectric between the adjacent top interconnect wires can be improved, consistency of the compositions of the insulated dielectric between the relative areas between the adjacent top interconnect wires is improved correspondingly, and thus the RC delay performance of the semiconductor structure is improved remarkably.

In other implementations, the top conductive layers may also be a conductive structure for implementing actions of other functions.

For example, in other implementations, the bottom film layer structure includes a plurality of floating gate material layers extending in a first direction and arranged in a second direction; the top conductive layers are control gate layers, the control gate layers are located on the floating gate material layers of the first regions and extend in the second direction, and the plurality of control gate layers are arranged in sequence in the first direction; and the grooves penetrate through the floating gate material layers located in the second regions, and the rest of the floating gate material layers located in the first regions are configured to serve as a floating gate layer.

In this implementation, the forming space can also be provided for the first dielectric layer at the bottoms of the openings by means of arrangement of the grooves, so that the bottoms of the air gaps enclosed in the first dielectric layer located in the grooves and the openings can be lower than the bottoms of the control gate layers, thus proportion consistency of the air gaps in the insulated dielectric between the adjacent control gate layers is improved advantageously, consistency of the compositions of the insulated dielectric between the relative areas between the adjacent control gate layers is improved correspondingly. Thus, consistency and stability of the capacitance value between the adjacent control gate layers are improved correspondingly, and the performance of the semiconductor structure is improved correspondingly.

In this implementation, the grooves penetrate through the floating gate material layers located in the second regions, so that the rest of the floating gate material layers located in the first regions are configured to serve as a floating gate layer, thus patterning of the floating gate layer can also be implemented while the grooves are configured to provide the forming space for the first dielectric layer at the bottoms of the openings, and process compatibility is improved correspondingly.

A semiconductor structure provided by these implementations may be formed by a forming method of a semiconductor structure provided by the present disclosure, or may also be formed by other methods.

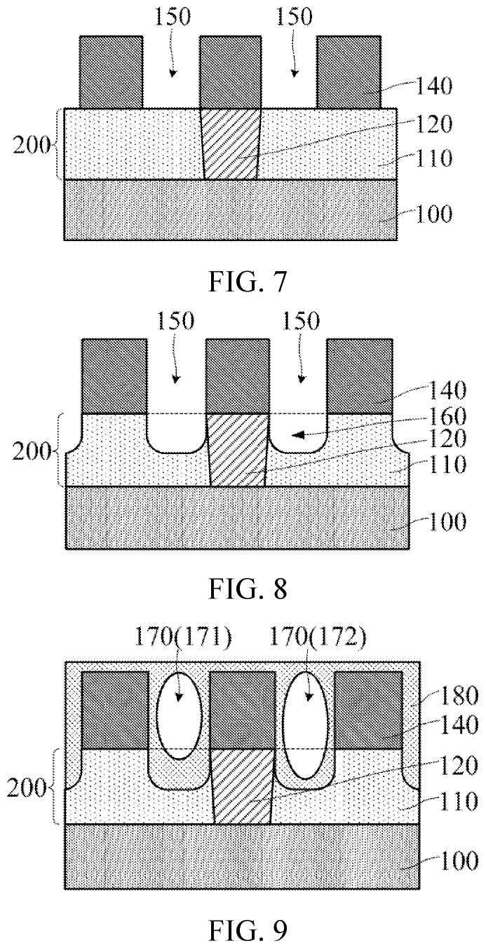

The present disclosure further provides a forming method of a semiconductor structure. FIG. 5 to FIG. 9 are corresponding schematic structural diagrams of steps in one form of of a forming method of a semiconductor structure of the present disclosure.

One form of a forming method of the semiconductor structure is described in detail below with reference to accompanying drawings.

Referring to FIG. 5, a base (not shown in the figures) is provided, where a bottom film layer structure 200 is formed on the base and includes a plurality of discrete first regions I and second regions II located among the first regions I.

The base is configured to provide a process platform for a subsequent process procedure.

As an example, in the step of providing the base, the base includes a substrate and a functional structure located on the substrate, for example: the functional structure may include a semiconductor device such as an MOS transistor, a resistor structure and the like. As an example, the MOS transistor includes a gate structure located on the substrate and a source/drain doped region in the substrate on two sides of the gate structure.

The bottom film layer structure 200 is configured to provide a platform for forming of the top conductive layers 140.

The bottom film layer structure 200 of the first regions I is configured to provide a process platform for forming the top conductive layers 140, and the bottom film layer structure 200 of the second regions II is configured to form the grooves 160.

As an example, the bottom film layer structure 200 includes conductive plugs 120 located in at least a part of the first regions I and a second dielectric layer 110 located between the conductive plugs 120.

The conductive plugs 120 are configured to be electrically connected with the top conductive layers 140 so that an electrical connection between the top conductive layers 140 and the functional structure in the base is implemented through the conductive plugs 120.

A material of the conductive plugs 120 is a conductive material. As an example, the material of the conductive plugs 120 is metal. In this implementation, the material of the conductive plugs 120 is Cu. In other implementations, the material of the conductive plugs may also be Al, W, Co and other conductive materials.

The second dielectric layer 110 is configured to implement an electrical isolation between the conductive plugs 120.

A material of the second dielectric layer 110 is an insulated dielectric material. As an example, the material of the second dielectric layer 110 may be a low-k dielectric material, an ultra-low-k dielectric material, silicon oxide, silicon nitride or silicon oxynitride and other dielectric materials.

It is to be noted that in this implementation, in the step of providing the base, a third dielectric layer (not shown in the figures) is further formed between the base and the bottom film layer structure 200, and bottom interconnect wires 100 are formed in the third dielectric layer. Correspondingly, the conductive plugs 120 are located on the bottom interconnect wires 100 and make contact with the bottom interconnect wires 100.

The bottom interconnect wires 100 make contact with the conductive plugs 120, so that an electrical connection between the bottom interconnect wires 100 and the top conductive layers 140 is implemented through the conductive plugs 120.

In this implementation, the bottom interconnect wires 100 are electrically connected with the functional structure in the base, so that the electrical connection between the functional structure in the base and the top conductive layers 140 is implemented through the bottom interconnect wires 100 and the conductive plugs 120.

A material of the bottom interconnect wires 100 is a conductive material. As an example, the material of the bottom interconnect wires 100 is metal. In this implementation, the material of the bottom interconnect wires 100 is Cu. In other implementations, the material of the bottom interconnect wires may also be Al, W, Co and other conductive materials.

The third dielectric layer is configured to implement an electrical isolation between the bottom interconnect wires.

A material of the third dielectric layer is an insulated dielectric material. As an example, the material of the third dielectric layer may be a low-k dielectric material, an ultra-low-k dielectric material, silicon oxide, silicon nitride or silicon oxynitride and other dielectric materials.

Referring to FIG. 6 to FIG. 7, the top conductive layers 140 are formed on the bottom film layer structure 200 of the first regions I, and openings 150 are enclosed between the adjacent top conductive layers 140 and the bottom film layer structure 200.

The top conductive layers 140 are configured to implement an electrical connection between the semiconductor structure and an external circuit or other interconnect structures.

In this implementation, the top conductive layers 140 make contact with the conductive plugs 120 to be electrically connected with the conductive plugs 120 so as to implement the electrical connection with the functional structure in the base through the conductive plugs 120.

More specifically, in this implementation, the top conductive layers 140 are configured to serve as top interconnect wires to be electrically connected with the bottom interconnect wires 100 through the conductive plugs 120.

As an example, an extension direction of the top interconnect wires is perpendicular to an extension direction of the bottom interconnect wires 100. In other implementations, the extension direction of the top interconnect wires may also be the same as the extension direction of the bottom interconnect wires.

In this implementation, the openings 150 are enclosed between the adjacent top conductive layers 140 and configured to enclose air gaps together with a subsequently formed first dielectric layer.

A material of the top conductive layers 140 is a conductive material. As an example, the material of the top conductive layers 140 is metal. In this implementation, the material of the top conductive layers 140 is Cu. In other implementations, the material of the top conductive layers may also be Al, W, Co, Ni and other conductive materials.

As an example, a step of forming the top conductive layers 140 includes: as shown in FIG. 6, a top conductive material layer 130 covers the bottom film layer structure 200; and as shown in FIG. 7, the top conductive material layer 130 located in the second regions II is removed, and the rest of the top conductive material layer 130 located in the first regions I is configured to serve as the top conductive layers 140.

The top conductive material layer 130 is configured to form the top conductive layers 140.

As an example, any one or several processes among a physical vapor deposition process, a chemical vapor deposition process and an electrochemical coating process may be adopted to form the top conductive layers 140.

The top conductive material layer 130 located in the second regions II is removed so as to implement patterning of the top conductive material layer 130.

As an example, a metal subtractive etch process is adopted to remove the top conductive material layer 130 located in the second regions II. For example: a wet etching process is adopted to remove the top conductive material layer 130 located in the second regions II.

In this implementation, the top conductive layers 140 are formed in a mode of removing the top conductive material layer 130 located in the second regions II after forming the top conductive material layer 130, so that the grooves are formed in the bottom film layer structure 200 at the bottoms of the openings 150 in a subsequent process step of removing the top conductive material layer 130 located in the second regions II, thus a process of forming the grooves is integrated with a process of forming the top conductive layers 140 advantageously, and then a process integration degree and process compatibility are improved.

The process step of forming the top conductive layers 140 is not limited to this. For example: in other implementations, the step of forming the top conductive layers may include: a sacrificial layer is formed on the bottom film layer structure of the second regions, and a filling groove is enclosed between the sacrificial layer and the bottom film layer structure located in the first regions; the top conductive layers are formed in the filling groove; and the sacrificial layer is removed after the top conductive layers are formed.

Referring to FIG. 8, the grooves 160 are formed in the bottom film layer structure 200 at the bottoms of the openings 150, and the bottoms of the grooves 160 are lower than bottoms of the top conductive layers 140.

The grooves 160 are located in the bottom film layer structure 200 at the bottoms of the openings 150, and the bottoms of the grooves 160 are lower than the bottoms of the top conductive layers 140, so that the grooves 160 can provide a forming space for the subsequent first dielectric layer at the bottoms of the openings 150, the first dielectric layer located in the grooves 160 is prevented from occupying too much space of the openings 150 advantageously, and thus the bottoms of the air gaps enclosed in the first dielectric layer located in the grooves 160 and the openings 150 can be caused to be lower than the bottoms of the top conductive layers 140.

In this implementation, the top conductive layers 140 are configured to serve as top interconnect wires; and in the step of forming the grooves 160, the second dielectric layer 110 with part of thickness also remains at the bottoms of the grooves 160, so that the bottoms of the grooves 160 are prevented from exposing the bottom interconnect wires 100, and thus it is conducive to guaranteeing completeness of the bottom interconnect wires 100 and electrical connection performance of the semiconductor structure.

Correspondingly, in this implementation, the grooves 160 are located in the second dielectric layer 110 with part of thickness in the second regions II.

It is to be noted that in the step of forming the grooves 160, depths of the grooves 160 are not suitable for being too small or too large. If the depths of the grooves 160 are too small, the space provided by the grooves 160 for the first dielectric layer at the bottoms of the openings 150 is prone to being too small, and then the bottoms of the air gaps enclosed in the first dielectric layer located in the grooves 160 and the openings 150 are prone to being higher than the bottoms of the top conductive layers 140; and if the depths of the grooves 160 are too large, depth-to-width ratios of the grooves 160 are prone to being too large, process difficulty of forming the grooves 160 is prone to increasing correspondingly, and moreover, a risk of exposing the bottom interconnect wires 100 is also prone to increasing in the process of forming the grooves 160. Therefore, in this implementation, in the step of forming the grooves 160, the depth of each groove 160 is 100 Ångström to 200 Ångström.

As an example, in the step of removing the top conductive material layer 130 located in the second regions II, the grooves 160 are formed in the bottom film layer structure 200 at the bottoms of the openings 150, so that the process of forming the grooves 160 is integrated with the process of forming the top conductive layers 140 advantageously, and thus the process integration degree and the processing compatibility are improved.

As an example, an anisotropic dry etching process is adopted to form the grooves 160 in the bottom film layer structure 200 exposed out of the top conductive layers 140. The anisotropic dry etching process has an anisotropic etching characteristic and is conducive to improving control over sections of the grooves 160, and moreover, etching precision of the anisotropic dry etching process is high, and control precision of the depths of the grooves 160 is improved advantageously.

In some implementations, a fluorine-containing plasma etching process may be adopted to form the grooves 160 in the bottom film layer structure 200 exposed out of the top conductive layers 140.

Referring to FIG. 9, the first dielectric layer 180 is formed on the top conductive layers 140 and further located in the grooves 160, the first dielectric layer 180 seals tops of the openings 150 to enclose the air gaps 170 together with the openings 150, and bottoms of the air gaps 170 are lower than the bottoms of the top conductive layers 140.

The first dielectric layer 180 is configured to implement an electrical isolation between the adjacent top conductive layers 140.

The first dielectric layer 180 is configured to seal the tops of the openings 150 and enclose the air gaps 170 together with the openings 150, the air gaps 170 have a dielectric constant lower than that of a common dielectric material (such as: the low-k dielectric material or the ultra-low-k dielectric material) in a semiconductor process, and thus parasitic capacitance between the adjacent top conductive layers 140 is reduced advantageously, an RC delay is reduced, and then the performance of the semiconductor structure is improved.

Besides, in this implementation, the first dielectric layer 180 is further located in the grooves 160, the forming space can be provided for the first dielectric layer 180 at the bottoms of the openings 150 by means of arrangement of the grooves 160, and the first dielectric layer 180 is prevented from occupying too much space of the openings 150, so that the bottoms of the air gaps 170 enclosed in the first dielectric layer 180 located in the grooves 160 and the openings 150 can be lower than the bottoms of the top conductive layers 140, thus improvement of proportion consistency of the air gaps 170 in the insulated dielectric between the adjacent top conductive layers 140 is facilitated, consistency of the compositions of the insulated dielectric between the relative areas between the adjacent top conductive layers 140 is improved correspondingly, thus consistency and stability of the capacitance value between the adjacent top conductive layers 140 are improved, the RC delay performance of the semiconductor structure is improved, and the performance of the semiconductor structure is improved.

As an example, in the step of forming the first dielectric layer 180, the first dielectric layer 180 is formed at tops and side walls of the top conductive layers 140 and in the grooves 160, with gradual increase of a deposition thickness of a material of the first dielectric layer 180, a deposition rate of the first dielectric layer 180 on the top conductive layers 140 and at top corners of the top conductive layers is greater than a deposition rate in the openings 150 and the grooves 160, so that before the first dielectric layer 180 fully fills the grooves 160 and the openings 150, the first dielectric layer 180 located at the top corners of the top conductive layers 140 makes contact in advance so as to seal the tops of the openings 150, and the first dielectric layer 180 located in the grooves 160 and the openings 150 encloses the air gaps 170.

As an example, in some implementations, sizes and positions of the air gaps 170 in various positions are different, for example: a bottom of the air gap 172 is lower than a bottom of the air gap 171, the bottoms of the air gaps 170 in the various positions are all lower than the bottoms of the top conductive layers 140 due to arrangement of the grooves 160, so that it is guaranteed that height proportion consistency of heights of the air gaps 170 in the various positions between the adjacent conductive layers 140 is good, thus proportion consistency of the air gaps 170 in the insulated dielectric between the adjacent top conductive layers 140 is improved advantageously, consistency of the compositions of the insulated dielectric between the relative areas between the adjacent top conductive layers 140 is improved correspondingly, and thus consistency and stability of the capacitance value between the adjacent top conductive layers 140 are improved.

A material of the first dielectric layer 180 is an insulated dielectric material. As an example, the material of the first dielectric layer 180 may be a low-k dielectric material, an ultra-low-k dielectric material, silicon oxide, silicon nitride or silicon oxynitride and other dielectric materials.

In this implementation, a deposition process with weak step coverage capability is adopted to form the first dielectric layer 180, so as to prevent the first dielectric layer 180 from fully filling the openings 150, correspondingly, it is guaranteed that while the first dielectric layer 180 located in the openings 150 and the grooves 160 can enclose the air gaps 170, the first dielectric layer 180 at the top corners of the top conductive layers 140 can make contact in advance, so as to seal the tops of the openings 150.

As an example, the process of forming the first dielectric layer 180 includes the chemical vapor deposition process. The chemical vapor deposition process is mature, low in process cost and high in process compatibility. In other implementations, other deposition processes with weak step coverage capability may also be adopted to form the first dielectric layer based on actual process demands.

It is to be noted that in this implementation, a description is made by taking the top conductive layers 140 being top interconnect wires as an example, and the bottom film layer structure with part of thickness also remains at the bottoms of the grooves 160 correspondingly. Correspondingly, by means of the forming method of the semiconductor structure provided by this embodiment, the proportion consistency of the air gaps 170 in the insulated dielectric between the adjacent top interconnect wires can be improved, the consistency of the compositions of the insulated dielectric between the relative areas between the adjacent top interconnect wires is improved correspondingly, and thus the RC delay performance of the semiconductor structure is improved remarkably.

In other implementations, the top conductive layers may also be a conductive structure for implementing actions of other functions.

For example: in the step of the providing the base, the bottom film layer structure includes a plurality of floating gate material layers extending in a first direction and arranged in a second direction, and the floating gate material layers are located in the first regions and the second regions.

Correspondingly, in the step of forming the top conductive layers on the bottom film layer structure of the first regions, the top conductive layers are control gate layers, the control gate layers are located on the floating gate material layers of the first regions and extend in the second direction, and the plurality of control gate layers are arranged in sequence in the first direction.

Correspondingly, in the step of forming the grooves in the bottom film layer structure at the bottoms of the openings, the floating gate material layers located in the second regions are removed, and the rest of the floating gate material layers located in the first regions are configured to serve as a floating gate layer.

In this implementation, the forming space can also be provided for the first dielectric layer at the bottoms of the openings by means of arrangement of the grooves, so that the bottoms of the air gaps enclosed in the first dielectric layer located in the grooves and the openings can be lower than the bottoms of the control gate layers, thus proportion consistency of the air gaps in the insulated dielectric between the adjacent control gate layers is improved advantageously, consistency of the compositions of the insulated dielectric between the relative areas between the adjacent control gate layers is improved correspondingly, thus consistency and stability of the capacitance value between the adjacent control gate layers are improved correspondingly, and the performance of the semiconductor structure is improved correspondingly.

In this implementation, the grooves penetrate through the floating gate material layers located in the second regions, so that the rest of the floating gate material layers located in the first regions are configured to serve as a floating gate layer, thus patterning of the floating gate layer can also be implemented while the grooves are configured to provide the forming space for the first dielectric layer at the bottoms of the openings, and process compatibility is improved correspondingly.

The present disclosure is described above but is not limited to this. Any person of skill in the art can make various changes and modifications without departing from the spirit and scope of the present disclosure, so the protection scope of the present disclosure should be subject to the scope limited by Claims.

What is claimed is:

1. A semiconductor structure, comprising:
a base;
a bottom film layer structure, located on the base and comprising a plurality of discrete first regions and a plurality of second regions located among the first regions;
top conductive layers, located on the bottom film layer structure of the first regions, wherein openings are enclosed between adjacent top conductive layers and the bottom film layer structure;
grooves, located in the bottom film layer structure at bottoms of the openings, wherein bottoms of the grooves are lower than bottoms of the top conductive layers; and
a first dielectric layer, located on the top conductive layers and further located in the grooves, wherein the first dielectric layer seals tops of the openings and encloses air gaps together with the openings, and bottoms of the air gaps are lower than the bottoms of the top conductive layers.

2. The semiconductor structure according to claim 1, wherein:
the bottom film layer structure comprises conductive plugs located in at least a part of the first regions and a second dielectric layer located between the conductive plugs;
the top conductive layers are configured to serve as top interconnect wires; and
the second dielectric layer is positioned at the bottoms of the grooves.

3. The semiconductor structure according to claim 2, wherein a depth of each groove is 100 Ångström to 200 Ångström.

4. The semiconductor structure according to claim 3, wherein:
a third dielectric layer is further formed between the base and the bottom film layer structure,
bottom interconnect wires are formed in the third dielectric layer, and
the conductive plugs are located on the bottom interconnect wires and make contact with the bottom interconnect wires.

5. The semiconductor structure according to claim 1, wherein:
the bottom film layer structure comprises a plurality of floating gate material layers extending in a first direction and arranged in a second direction;
the top conductive layers are control gate layers, the control gate layers are located on the floating gate material layers in the first regions and extend in the second direction, and the plurality of control gate layers are arranged in sequence in the first direction; and
the grooves penetrate through the floating gate material layers located in the second regions, and the remaining of the floating gate material layers located in the first regions are configured to serve as a floating gate layer.

6. A forming method of a semiconductor structure, comprising:
providing a base, wherein a bottom film layer structure is formed on the base and comprises a plurality of discrete first regions and a plurality of second regions located among the first regions;
forming top conductive layers on the bottom film layer structure of the first regions, wherein openings are enclosed between the adjacent top conductive layers and the bottom film layer structure;
forming grooves in the bottom film layer structure at bottoms of the openings, wherein bottoms of the grooves are lower than bottoms of the top conductive layers; and
forming a first dielectric layer on the top conductive layers, wherein the first dielectric layer is further located in the grooves, seals tops of the openings and encloses air gaps together with the openings, and bottoms of the air gaps are lower than the bottoms of the top conductive layers.

7. The forming method of the semiconductor structure according to claim 6, wherein the step of forming the top conductive layers comprises:
covering the bottom film layer structure with a top conductive material layer; and
removing the top conductive material layer located in the second regions and using the remainder of the top conductive material layer located in the first regions as the top conductive layers.

8. The forming method of the semiconductor structure according to claim 7, wherein in the step of removing the top conductive material layer located in the second regions, the grooves are formed in the bottom film layer structure at the bottoms of the openings.

9. The forming method of the semiconductor structure according to claim 6, wherein:
the bottom film layer structure comprises conductive plugs located in at least a part of the first regions and a second dielectric layer located between the conductive plugs;
the top conductive layers are configured to serve as top interconnect wires; and
the second dielectric layer with part of thickness also remains at the bottoms of the grooves in the step of forming the grooves.

10. The forming method of the semiconductor structure according to claim 9, wherein in the step of forming the grooves, a depth of each groove is 100 Ångström to 200 Ångström.

11. The forming method of the semiconductor structure according to claim 9, wherein:
in the step of providing the base, a third dielectric layer is further formed between the base and the bottom film layer structure, and bottom interconnect wires are formed in the third dielectric layer; and
the conductive plugs are located on the bottom interconnect wires and make contact with the bottom interconnect wires.

12. The forming method of the semiconductor structure according to claim 6, wherein an anisotropic dry etching process is adopted to form the grooves in the bottom film layer structure exposed out of the top conductive layers.

13. The forming method of the semiconductor structure according to claim 6, wherein a process of forming the first dielectric layer comprises a chemical vapor deposition process.

14. The forming method of the semiconductor structure according to claim 6, wherein:
in the step of providing the base, the bottom film layer structure comprises a plurality of floating gate material layers extending in a first direction and arranged in a second direction, and the floating gate material layers are located in the first regions and the second regions;
in the step of forming the top conductive layers on the bottom film layer structure of the first regions, the top conductive layers are control gate layers, the control gate layers are located on the floating gate material layers of the first regions and extend in the second direction, and the plurality of control gate layers are arranged in sequence in the first direction; and
in the step of forming the grooves in the bottom film layer structure at the bottoms of the openings, the floating gate material layers located in the second regions are removed, and the rest of the floating gate material layers located in the first regions are configured to serve as a floating gate layer.
